(19) United States
(12) Patent Application Publication
(10) Pub. No.: US 2015/0303295 A1
(43) Pub. Date: Oct. 22, 2015

(54) SELF-ALIGNED CONTACT OPENINGS OVER FINS OF A SEMICONDUCTOR DEVICE

(71) Applicant: GLOBALFOUNDRIES Inc., Grand Cayman (KY)

(72) Inventors: Jing Wan, Malta, NY (US); Xiang Hu, Clifton Park, NY (US); Jinping Liu, Ballston Lake, NY (US); Gabriel Padron Wells, Saratoga Springs, NY (US); Andy Chih-Hung Wei, Queensbury, NY (US); Guillaume Bouche, Albany, NY (US); Cuiqin Xu, Malta, NY (US)

(73) Assignee: GLOBALFOUNDRIES Inc., Grand Cayman (KY)

(21) Appl. No.: 14/258,279

(22) Filed: Apr. 22, 2014

(51) Int. Cl. H01L 29/78; H01L 29/51; H01L 29/66

(52) U.S. Cl. CPC H01L 29/785; H01L 29/66795; H01L 29/66545; H01L 29/517; H01L 2029/7858

(57) ABSTRACT

Approaches for forming a set of contact openings in a semiconductor device (e.g., a FinFET device) are provided. Specifically, the semiconductor device includes a set of fins formed in a substrate, a gate structure (e.g., replacement metal gate (RMG)) formed over the substrate, and a set of contact openings adjacent the gate structure, each of the set of contact openings having a top section and a bottom section, wherein a width of the bottom section, along a length of the gate structure, is greater than a width of the top section. The semiconductor device further includes a set of metal contacts formed within the set of contact openings.

### BACKGROUND

1. Technical Field

This invention relates generally to the field of semiconductors, and more particularly, to approaches used to form a set of self-aligned contact openings in a semiconductor device.

2. Related Art

A typical integrated circuit (IC) chip includes a stack of several levels or sequentially formed layers of shapes. Each layer is stacked or overlaid on a prior layer and patterned to form the shapes that define devices (e.g., fin field effect transistors (FinFETs)) and connect the devices into circuits. In a typical state of the art, complementary insulated gate FinFET process, such as what is normally referred to as CMOS, layers are formed on a wafer to form the devices on a surface of the wafer. Further, the surface may be the surface of a silicon layer on a silicon on insulator (SOI) wafer. A simple FINFET is formed by the intersection of two shapes, i.e., a gate layer rectangle on a silicon island formed from the silicon surface layer. Each of these layers of shapes, also known as mask levels or layers, may be created or printed optically through well-known photolithographic masking, developing, and level definition, e.g., etching, implanting, deposition, etc.

Silicon based FinFETs have been successfully fabricated using conventional MOSFET technology. A typical FinFET is fabricated on a substrate with an overlying insulating layer with a thin ‘fin’ extending from the substrate, for example, etched into a silicon layer of the substrate. The channel of the FET is formed in this vertical fin. A gate is provided over the fin(s). A double gate is beneficial in that there is a gate on both sides of the channel allowing gate control of the channel from both sides. Further advantages of FinFETs include reducing the short channel effect and higher current flow. Other FinFET architectures may include three or more effective gates.

As scaling of FinFET devices continues to accelerate, a number of problems arise with current self-aligned contact (SAC) schemes. For example, spacing between adjacent contacts is tight at a top section thereof, which creates a risk of shorting, contact to fin overlap is reduced to increase spacing between contacts, which leads to resistance variation, and a dry etch used to form the contacts gouges an epitaxial region, thus reducing contact area.

### SUMMARY

In general, approaches for forming a set of contact openings in a semiconductor device (e.g., a FinFET device) are provided. Specifically, the semiconductor device includes a set of fins formed in a substrate, a gate structure (e.g., replacement metal gate (RMG)) formed over the substrate, and a set of contact openings adjacent the gate structure, each of the set of contact openings having a top section and a bottom section, wherein a width of the bottom section, along a length of the gate structure, is greater than a width of the top section. The semiconductor device further includes a set of metal contacts formed within the set of contact openings. With this structure, the semiconductor device includes larger gaps between neighboring contacts, which reduces the potential for a short circuit, provides better contact formation with the source/drain due to the size of the bottom section of the contact openings, and allows the use of a mild wet etching (e.g., instead of dry etching), which causes less gauging of the substrate.

One aspect of the present invention includes a semiconductor device comprising: a set of fins formed in a substrate; a gate structure formed over the substrate; and a set of contact openings adjacent the gate structure, each of the set of contact openings having a top section and a bottom section, wherein a width of the bottom section, along a length of the gate structure, is greater than a width of the top section.

Another aspect of the present invention includes a method for forming a semiconductor device, the method comprising: providing a set of fins formed in a substrate; forming a gate structure over the substrate; and forming a set of contact openings adjacent the gate structure, each of the set of contact openings having a top section and a bottom section, wherein a width of the bottom section, along a length of the gate structure, is greater than the width of the top section.

Another aspect of the present invention includes a method for forming a set of contact openings in a semiconductor device, the method comprising: providing a set of fins formed within a substrate; forming a gate structure over the set of fins; and forming a set of contact openings adjacent the gate structure, each of the set of contact openings having a top section and a bottom section, wherein a width of the bottom section, along a length of the gate structure, is greater than the width of the top section.

### BRIEF DESCRIPTION OF THE DRAWINGS

These and other features of this invention will be more readily understood from the following detailed description of the various aspects of the invention taken in conjunction with the accompanying drawings in which:

FIG. 1(a) shows a cross-sectional view along a first direction of a semiconductor device according to illustrative embodiments;

FIG. 1(b) shows a cross-sectional view along a second direction, generally perpendicular to the first direction, of the semiconductor device according to illustrative embodiments;

FIGS. 2(a)-2(g) show cross-sectional views of processing steps for forming a set of contact openings in the semiconductor device according to an illustrative embodiment;

FIG. 2(h) shows a cross-sectional view of a set of metal contacts formed within the set of contact openings according to illustrative embodiments;

FIGS. 3(a)-3(e) show cross-sectional views of processing steps for forming a set of contact openings in the semiconductor device according to another illustrative embodiment;

FIG. 3(f) shows a cross-sectional view of a set of metal contacts formed within the set of contact openings according to illustrative embodiments; and

FIG. 4 shows a process flow for forming a set of contact openings in a semiconductor device according to illustrative embodiments.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

Furthermore, certain elements in some of the figures may be omitted, or illustrated not-to-scale, for illustrative clarity. The cross-sectional views may be in the form of “slices”, or “near-sighted” cross-sectional views, omitting certain background lines, which would otherwise be visible in a “true” cross-sectional view, for illustrative clarity. Also, for clarity, some reference numbers may be omitted in certain drawings.

### DETAILED DESCRIPTION

Exemplary embodiments will now be described more fully herein with reference to the accompanying drawings, in which exemplary embodiments are shown. It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure, e.g., a first layer, is present on a second element, such as a second structure, e.g., a second layer, wherein intervening elements, such as an interface structure, e.g., interface layer, may be present between the first element and the second element.

As used herein, “depositing” may include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

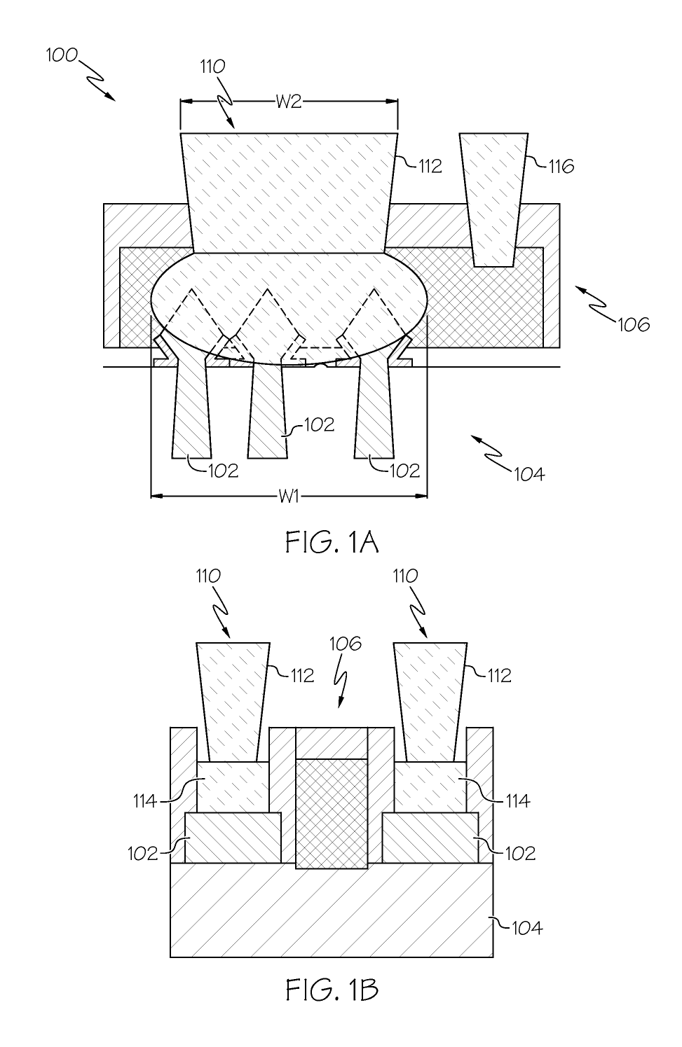

With reference now to the figures, FIG. 1(a) shows a side cross-sectional view of a semiconductor device (e.g., a FinFET device) 100 along a first direction, while FIG. 1(b) shows a front cross-sectional view of semiconductor device 100 along a second direction, which is generally perpendicular to the first direction. As shown, device 100 includes a set of fins 102 formed in a substrate 104, a gate structure 106 (e.g., replacement metal gate (RMG)) formed over substrate 104, and a set of contact openings 110 adjacent gate structure 106, each of set of contact openings 110 having a top section 112 and a bottom section 114, wherein a width (W1) of bottom section 114, along a length of gate structure 106 (e.g., extending across set of fins 102, as best shown in FIG. 1(a)), is greater than a width (W2) of top section 112. With this structure, semiconductor device 100 includes larger gaps between neighboring contacts, e.g., in an area between each top section 112, as well as between top section 112 and a second contact 116, which reduces the potential for a short circuit. Device 100 furthermore provides better contact formation with the source/drain due to the size of bottom section 114 of contact openings 110, and allows the use of a mild wet etching (e.g., instead of dry etching), which causes less damage to fins 102.

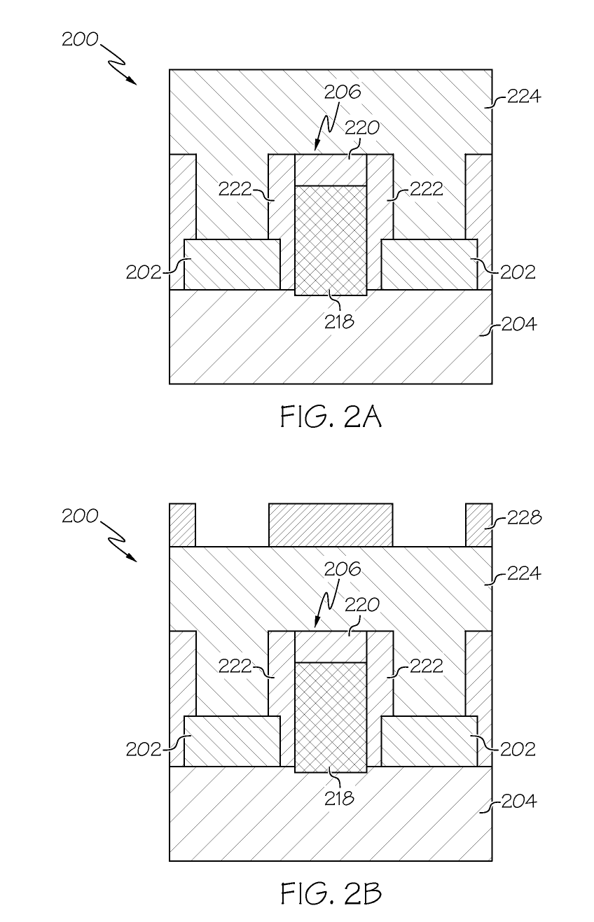

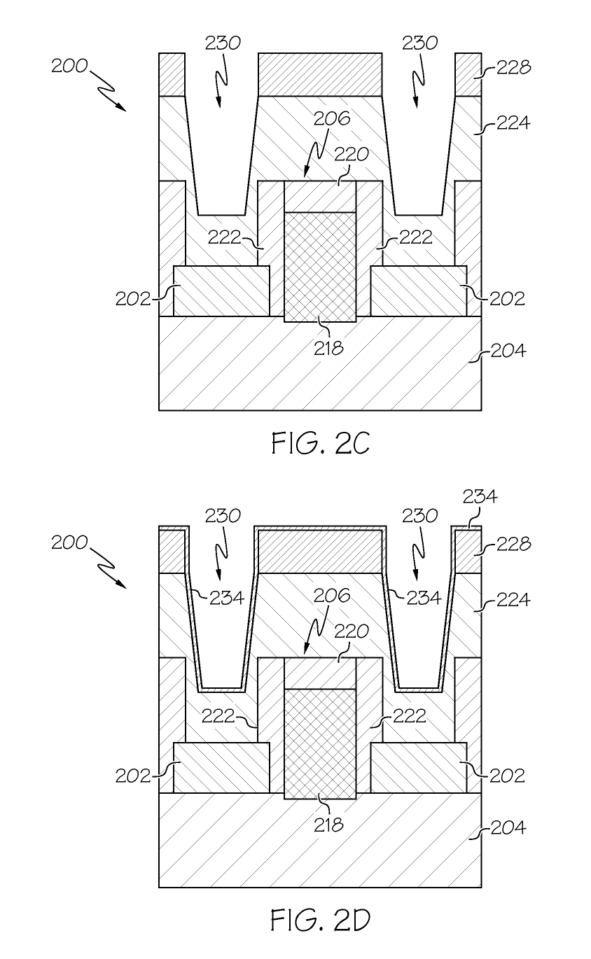

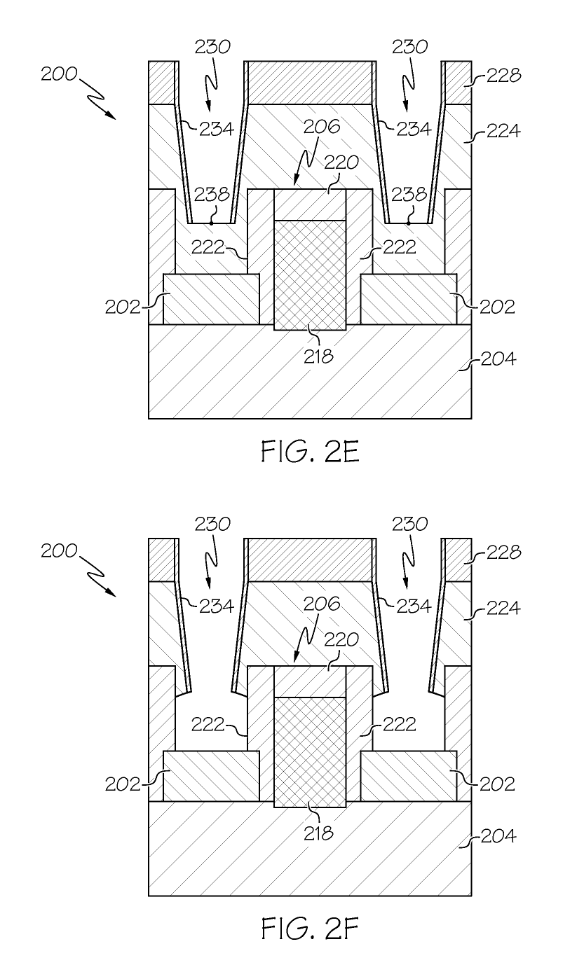

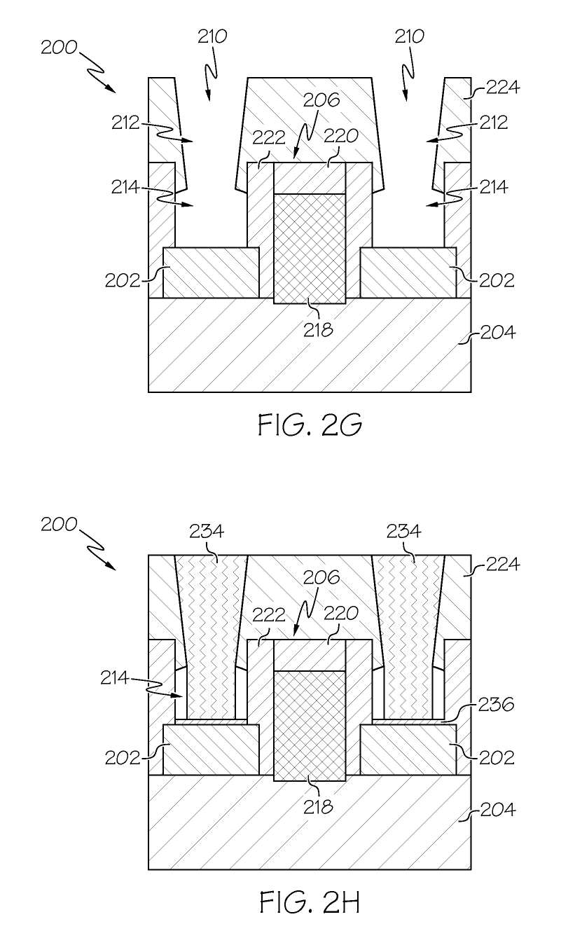

An exemplary approach for forming contact openings in a semiconductor device will be described in greater detail with reference to FIGS. 2(a)-2(h). FIG. 2(a) shows a cross sectional view of device 200, which comprises substrate 204 (e.g., bulk silicon) and set of fins 202 patterned (e.g., etched) from substrate 204. Fins 202 may be fabricated using any suitable process including one or more photolithography and etch processes. The photolithography process may include forming a photoresist layer (not shown) overlying substrate 204 (e.g., on a silicon layer), exposing the resist to a pattern, performing post-exposure bake processes, and developing the resist to form a masking element including the resist. The masking element may then be used to etch fins 202 into the silicon layer, e.g., using reactive ion etch (RIE) and/or other suitable processes. In one embodiment, fins 202 are formed using a sidewall image transfer technique. In another embodiment, fins 202 are formed by a double-patterning lithography (DPL) process. DPL is a method of constructing a pattern on a substrate by dividing the pattern into two interleaved patterns. DPL allows enhanced feature (e.g., fin) density. Various DPL methodologies may be used including, but not limited to, double exposure (e.g., using two mask sets), forming spacers adjacent features and removing the features to provide a pattern of spacers, resist freezing, and/or other suitable processes.

The term “substrate” as used herein is intended to include a semiconductor substrate, a semiconductor epitaxial layer deposited or otherwise formed on a semiconductor substrate and/or any other type of semiconductor body, and all such structures are contemplated as falling within the scope of the present invention. For example, the semiconductor substrate may comprise a semiconductor wafer (e.g., silicon, SiGe, or an SOI wafer) or one or more die on a wafer, and any epitaxial layers or other type of semiconductor layers formed thereover or associated therewith. A portion or entire semiconductor substrate may be amorphous, polycrystalline, or single-crystalline. In addition to the aforementioned types of semiconductor substrates, the semiconductor substrate employed in the present invention may also comprise a hybrid oriented (HOT) semiconductor substrate in which the HOT substrate has surface regions of different crystallographic orientation. The semiconductor substrate may be doped, undoped, or contain doped regions and undoped regions therein. The semiconductor substrate may contain regions with strain and regions without strain therein, or contain regions of tensile strain and compressive strain.

Device 200 further comprises gate structure 206, which may be a replacement (i.e., dummy) metal gate. As is known, RMG includes a dummy gate material that is later replaced with the metal gate material. The dummy gate material holds the position for the metal gate and prevents damage to the metal gate material that would occur to the metal gate material if it were in place during certain processing. Gate structure 206 has a gate body 218, which may include any now known or later developed material appropriate for holding a position within a dielectric layer. In one embodiment, dummy gate body 118 includes a polysilicon. Gate structure 206 further includes an optional capping layer 220, which may include, for example, silicon nitride (Si3N4). The structure shown in FIG. 2(a) may be formed using any now known or later developed techniques, e.g., material deposition, mask material deposition, patterning and etching, and etching to form the structure illustrated.

As also shown in FIG. 2(a), a spacer 222 may be formed about dummy gate body 218 and capping layer 220. Spacer 222 may be formed using conventional techniques, for example, deposition of silicon nitride (Si3N4) and reactive ion etching to form the shape of spacers 222. A dielectric layer 224 (e.g., an interlayer dielectric layer OLD)) is then formed over device 200 including over gate stack 206. Dielectric layer 224 may be formed via flowable chemical vapor deposition (FCVD) oxide filling and CMP. In other embodiments, dielectric layer 224 includes, but is not limited to: silicon nitride (Si3N4), silicon oxide (SiO2), fluorinated SiO2 (FSG), hydrogenated silicon oxycarbide (SiCOH), porous SiCOH, boro-phospho-silicate glass (BPSG), silsesquioxanes, carbon (C) doped oxides (i.e., organosilicates) that include atoms of silicon (Si), carbon (C), oxygen (O), and/or hydrogen (H), thermosetting polyarylene ethers, SILK (a polyarylene ether available from Dow Chemical Corporation), a spin-on silicon-carbon containing polymer material available form JSR Corporation, other low dielectric constant (<3.9) material, or layers thereof.

Although not specifically shown, it will be appreciated that forming the RMG may include any now known or later developed replacement gate techniques. For example, in one embodiment, forming of the RMG may include depositing a high dielectric constant (high-k) layer in a gate opening to form a gate dielectric layer. High-k layer may include, but is not limited to: hafnium silicate (HfSiO), hafnium oxide (HfO2), zirconium silicate (ZrSiOx), zirconium oxide (ZrO2), silicon oxide (SiO2), silicon nitride (Si3N4), silicon oxynitride (SiON), or any other high-k material (>4.0) or any combination of these materials. Next, a metal is deposited in gate opening(s). Although shown as a single material, it is understood that multiple metal depositions using appropriate masking techniques may be employed to provide the appropriate metal over the desired areas.

Next, a plurality of openings in device 200 are formed, beginning with deposition and patterning of a first hard mask 228 over dielectric layer 224, as shown by device 200 in FIG. 2(b), followed by an etch of dielectric layer 224 to form set of trenches 230 in dielectric layer 224, as shown by device 200 in FIG. 2(c). In one embodiment, set of trenches 230 are formed via an oxide etch, which stops before reaching fins 202.

A second hard mask 234 is then formed over first hard mask 228 and within set of trenches 230, as shown by device 200 in FIG. 2(d). Second hard mask 234 can be the same or different than the material of first hard mask 228 depending on deposition temperature, conformity, etching selectivity, etc. In one embodiment, second hard mask 234 comprises nitride (SiN) or ALD.

Next, second hard mask 234 is removed from a bottom surface 238 of set of trenches 230 and from atop first hard mask 228, as shown by device 200 in FIG. 2(e). Dielectric layer 224 is then removed from atop set of fins 202, as shown by device 200 in FIG. 2(f). In one embodiment, dielectric layer 224 is removed via isotropic (or partially isotropic) wet etching to the bottom residual oxide. Using this wet etch, as opposed to a dry etching, results in less damage to the silicon of fins 202.

First hard mask 228 and second hard mask 234 are then removed, as shown by device 200 in FIG. 2(g), resulting in set of contact openings 210 having bottom sections 214 and top sections 212, wherein bottom sections 214 are generally wider than top sections 212. Each top section 212 has tapered sidewalls resulting in a larger opening towards the top of device 200. This is additionally demonstrated by device 100 shown in FIG. 1(a), whereby device 100 includes set of contact openings 110 adjacent gate structure 106, each of set of contact openings having top section 112 and bottom section 114, wherein width (W1) of bottom section 114, along a length of gate structure 106 is greater than a width (W2) of top section 112.

Next, metallization of device 200 occurs, whereby a set of metal contacts 234 (e.g., Tungsten) is formed within set of contact openings 210, as shown by device 200 in FIG. 2(h). In one embodiment, a silicide layer 236 (e.g., Ti or Ni) is first deposited over fins 202 using a process with good conformity (e.g., ALD or MOCVD) to envelope all of fins 202. Tungsten is then deposited by PVD (POR) to form self-aligned metal contacts 234 over silicide layer 236.

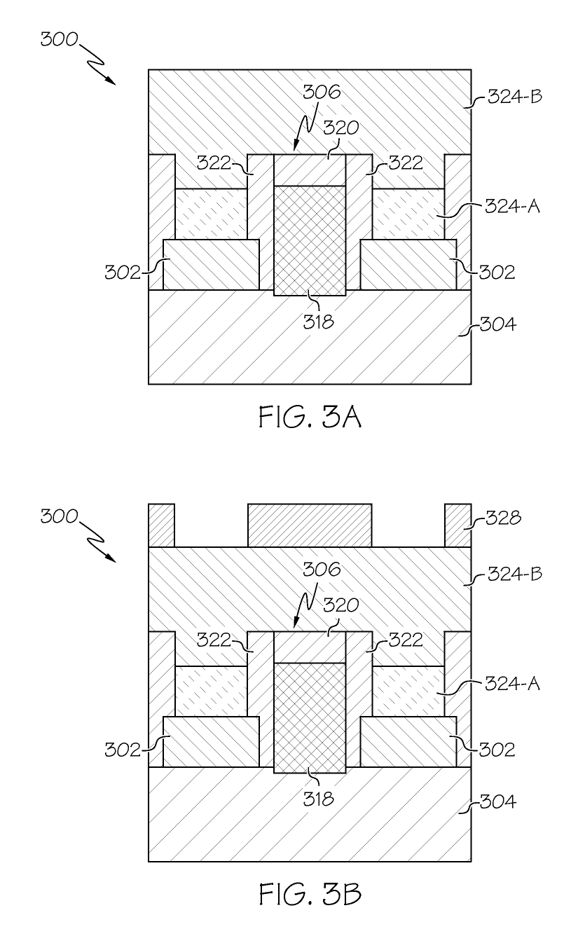

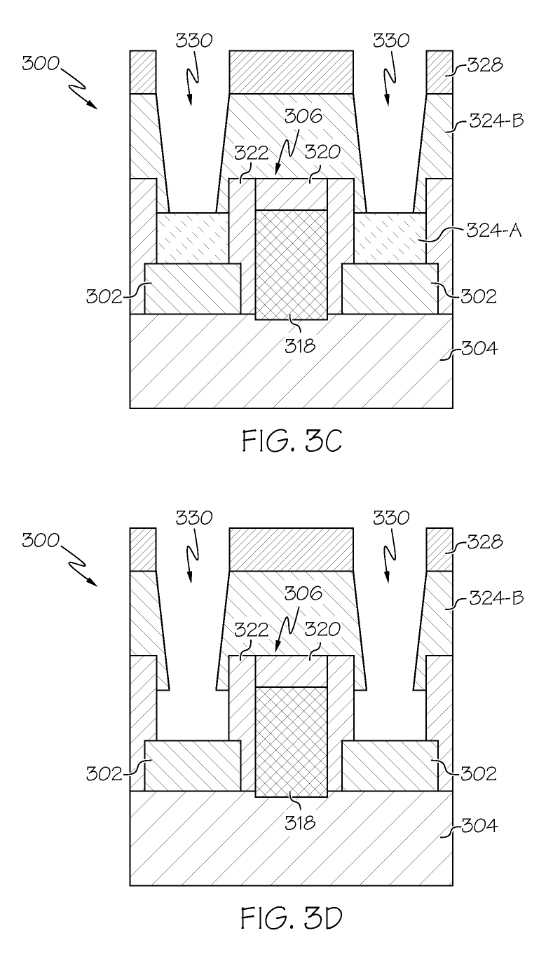

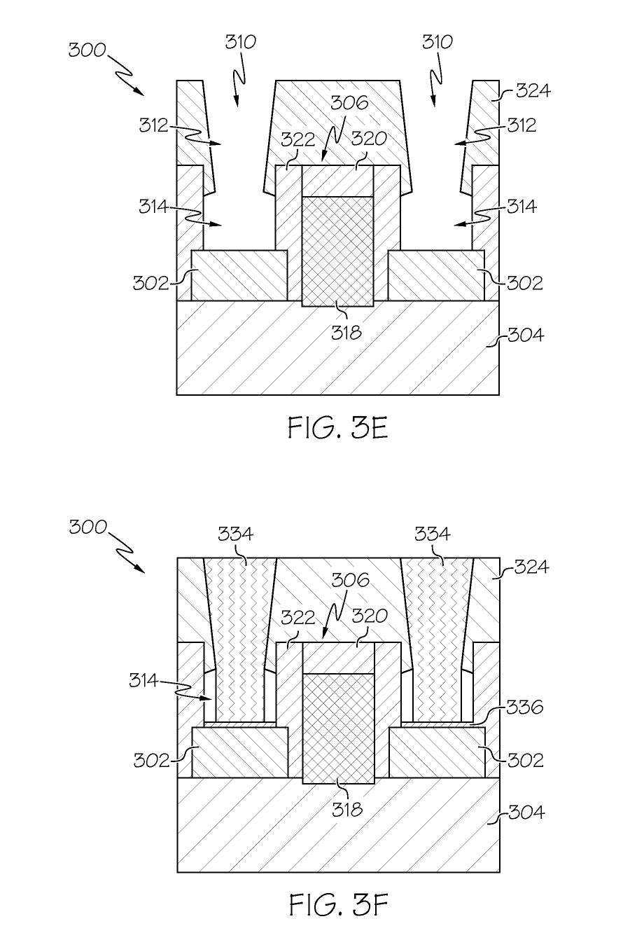

Turning now to FIGS. 3(a)-(f), another exemplary approach for forming contact openings in a semiconductor device will be described in greater detail. FIG. 3(a) shows a cross sectional view of device 300, which comprises substrate 304 (e.g., bulk silicon) and set of fins 302 patterned (e.g., etched) from substrate 304.

Device 300 further comprises gate structure 306, which may be a replacement (i.e., dummy) metal gate. Gate structure 306 has a gate body 318, which may include any now known or later developed material appropriate for holding a position within a dielectric layer. In one embodiment, dummy gate body 318 includes a polysilicon. Gate structure 306 further includes an optional capping layer 320, which may include, for example, silicon nitride (Si3N4). The structure shown in FIG. 3(a) may be formed using any now known or later developed techniques, e.g., material deposition, mask material deposition, patterning and etching, and etching to form the structure illustrated.

As also shown in FIG. 3(a), a spacer 322 may be formed about dummy gate body 318 and capping layer 320. Spacer 322 may be formed using conventional techniques, for example, deposition of silicon nitride (Si3N4) and reactive ion etching to form the shape of spacers 322. A dielectric layer 324A-B (e.g., an interlayer dielectric layer (ILD)) is then formed over device 300 including over gate stack 306. In this embodiment, dielectric layer 324A-B includes a first material 324-A (e.g., an oxide) formed atop fins 302, and a second material 324-B (e.g., a low-k material) formed over first material 324-A. In this embodiment, second material 324-B is a low dielectric constant (<3.9) material having etching selectivity to first material 324-A.

Next, a plurality of openings in device 300 are formed, beginning with deposition and patterning of a first hard mask 328 over dielectric layer 324-B, as shown by device 300 in FIG. 3(b), followed by an etch of dielectric layer 324 to form set of trenches 330 in dielectric layer 324-B, as shown by device 300 in FIG. 3(c). In one embodiment, set of trenches 330 is formed via an oxide etch selective to first material 324-A.

Next, first material 324-A is removed from atop fins 302, as shown by device 300 in FIG. 3(d). In one embodiment, dielectric layer 324-A is removed via isotropic (or partially isotropic) wet etching to the bottom residual oxide. Because second material 324-B has a low-k value, it can be directly used as ILD. Otherwise, it has to be removed and an oxide is needed to refill the gap.

First hard mask 328 is then removed, as shown by device 300 in FIG. 3(e), resulting in set of contact openings 310 having bottom sections 314 and top sections 312, wherein bottom sections 314 are generally wider than top sections 312. Each top section 312 has tapered sidewalls resulting in a larger opening towards the top of device 300. Again, this is additionally demonstrated by device 100 shown in FIG. 1(a), whereby device 100 includes set of contact openings 110 adjacent gate structure 106, each of set of contact openings having top section 112 and bottom section 114, wherein width (W1) of bottom section 114, along a length of gate structure 106 is greater than a width (W2) of top section 112.

Next, metallization of device 300 occurs, whereby a set of metal contacts 334 (e.g., Tungsten) is formed within set of contact openings 310, as shown by device 300 in FIG. 3(f). In one embodiment, a silicide layer 336 (e.g., Ti or Ni) is first deposited over fins 302 using a process with good conformity (e.g., ALD or MOCVD) to envelope all of fins 302. Tungsten is then deposited by PVD (POR) to form self-aligned metal contacts 334 over silicide layer 336. As a result, semiconductor device 300 includes larger gaps between neighboring contacts, e.g., in an area between each top section 312, as well as between top section 312 and a second contact 116 (FIG. 1(a)), which reduces the potential for a short circuit. Device 300 furthermore provides better contact formation with the source/drain due to the size of bottom section 314 of contact openings 310, and allows the use of a mild wet etching (e.g., instead of dry etching), which causes less damage to the silicon of fins 302.

In various embodiments, design tools can be provided and configured to create the datasets used to pattern the semiconductor layers as described herein. For example, data sets can be created to generate photomasks used during lithography operations to pattern the layers for structures as described herein, including a set of fins formed in a substrate, a gate structure formed over the substrate, and a set of contact openings adjacent the gate structure, each of the set of contact openings having a top section and a bottom section, wherein a width of the bottom section, along a length of the gate structure, is greater than a width of the top section. Such design tools can include a collection of one or more modules and can also be comprised of hardware, software, or a combination thereof. Thus, for example, a tool can be a collection of one or more software modules, hardware modules, software/hardware modules, or any combination or permutation thereof.

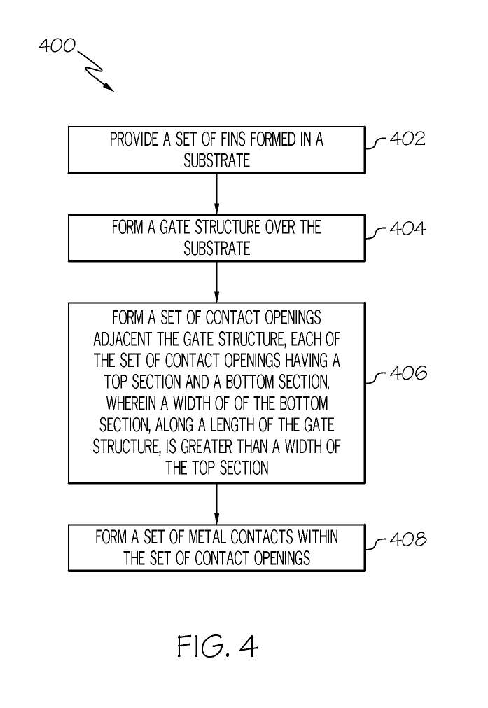

The software/hardware modules of the tool may be configured to perform a process 400, as shown in FIG. 4. Process 400 includes providing a set of fins from a substrate (402), forming a gate structure over the substrate (404), forming a set of contact openings adjacent the gate structure, each of the set of contact openings having a top section and a bottom section, wherein a width of the bottom section, along a length of the gate structure, is greater than the width of the top section (406), and forming a set of metal contacts within the set of contact openings (408).

As another example, the tool can be a computing device or other appliance on which software runs or in which hardware is implemented. As used herein, a module might be implemented utilizing any form of hardware, software, or a combination thereof. For example, one or more processors, controllers, ASICs, PLAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

It is apparent that there has been provided approaches for forming a set of contact openings in a semiconductor device. While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A semiconductor device comprising:
a set of fins formed in a substrate;
a gate structure formed over the substrate; and
a set of contact openings adjacent the gate structure, each of the set of contact openings having a top section and a bottom section, wherein a width of the bottom section, along a length of the gate structure, is greater than a width of the top section.

2. The semiconductor device of claim 1, further comprising a capping layer formed over the gate structure.

3. The semiconductor device of claim 1, wherein the gate structure comprises a replacement metal gate (RMG).

4. The semiconductor device of claim 1, further comprising a set of metal contacts formed within the set of contact openings.

5. The semiconductor device of claim 4, further comprising a silicide layer formed over the set of fins, wherein the set of metal contacts is formed over the silicide layer.

6. The semiconductor device according to claim 1, further comprising an interlayer dielectric (ILD), the ILD comprising at least one of: an oxide, and a low-k material.

7. A method for forming a semiconductor device, the method comprising:
providing a set of fins formed in a substrate;
forming a gate structure over the substrate; and
forming a set of contact openings adjacent the gate structure, each of the set of contact openings having a top section and a bottom section, wherein a width of the bottom section, along a length of the gate structure, is greater than the width of the top section.

8. The method according to claim 7, further comprising forming a capping layer over the gate structure.

9. The semiconductor device of claim 7, the forming the set of contact openings comprising:
forming an interlayer dielectric (ILD) over the gate structure;
patterning a first hard mask formed over the ILD;
forming a set of trenches in the ILD;
forming a second hardmask over the semiconductor device;
removing the second hardmask from a bottom surface of the set of trenches;
removing the ILD from atop the set of fins; and
removing the first and second hard masks.

10. The method according to claim 7, further comprising forming a set of metal contacts within the set of contact openings.

11. The method according to claim 7, further comprising forming a silicide layer over the set of fins.

12. The method according to claim 9, the ILD comprising an oxide.

13. The method according to claim 7, the forming the set of contact openings comprising:
forming an interlayer dielectric (ILD) over the gate structure, the ILD comprising a first material formed atop set of fins, and a second material formed atop the first material;
patterning a hard mask formed over the ILD;
forming a set of trenches in the ILD selective to the first material;
removing the first material from atop the set of fins; and
removing the hard mask.

14. A method for forming a set of contact openings in a semiconductor device, the method comprising:
providing a set of fins formed within a substrate;
forming a gate structure over the set of fins; and
forming a set of contact openings adjacent the gate structure, each of the set of contact openings having a top section and a bottom section, wherein a width of the bottom section, along a length of the gate structure, is greater than the width of the top section.

15. The method according to claim 14, further comprising forming a capping layer over the gate structure.

16. The semiconductor device of claim 14, the forming the set of contact openings comprising:
forming an interlayer dielectric (ILD) over the gate structure;
patterning a first hard mask formed over the ILD;
forming a set of trenches in the ILD;
forming a second hardmask over the semiconductor device;
removing the second hardmask from a bottom portion of the set of trenches;
removing the ILD from atop the set of fins; and
removing the first and second hard masks.

17. The method according to claim 14, further comprising forming a set of metal contacts within the set of contact openings.

18. The method according to claim 14, further comprising forming a silicide layer over the set of fins.

19. The method according to claim 14, the forming the set of contact openings comprising:
forming an interlayer dielectric (ILD) over the gate structure, the ILD comprising a first material formed atop set of fins, and a second material formed atop the first material;
patterning a hard mask formed over the ILD;
forming a set of trenches in the ILD selective to the first material;
removing the first material from atop the set of fins; and
removing the hard mask.

20. The method according to claim 19, the first material comprising an oxide material, and the second material comprising a low-k material.
